(19) United States
(12) Patent Application Publication
(10) Pub. No.: US 2010/0307588 A1
(43) Pub. Date: Dec. 9, 2010

(54) Solar cell structures

(76) Inventors: Jung-hyun Lee, Suwon-si (KR); Dong-joon Ma, Anyang-si (KR)

Correspondence Address: HARNESS, DICKEY & PIERCE, P.L.C., P.O. BOX 8910, RESTON, VA, 20195, US

(21) Appl. No.: 12/801,194

(22) Filed: May 27, 2010

(30) Foreign Application Priority Data
Jun. 2, 2009 (KR) 10-2009-0048651

(51) Int. Cl. H01L 31/0256; H01L 31/00

(52) U.S. Cl. 136/260; 136/252; 136/264; 136/265

(57) ABSTRACT

Solar cell structures including an n-type semiconductor layer, an i-type semiconductor layer on the n-type semiconductor layer, and a p-type semiconductor layer on the i-type semiconductor layer. The n-type semiconductor layer and the p-type semiconductor layer each respectively contacts a transparent conductive layer having a transparent conductive material.

### CROSS-REFERENCE TO RELATED APPLICATIONS

This application claims the benefit of priority under 35 U.S.C §119 from Korean Patent Application No. 10-2009-0048651, filed on Jun. 2, 2009, in the Korean Intellectual Property Office, the disclosure of which is incorporated herein in its entirety by reference.

### BACKGROUND

1. Field

Example embodiments relate to solar cell structures shaving a transparent conductor material formed on a surface of each of a p-type semiconductor layer and an n-type semiconductor layer.

2. Description of the Related Art

Solar cells are devices that convert light into electricity using semiconductor technology. Solar cells are manufactured using various materials (e.g., silicon (Si), copper indium gallium selenide (CIGS) and cadmium telluride (CdTe)). In general, a solar cell is configured as a P-N junction diode that is formed by combining p-type and n-type semiconductors together in very close contact. Once light is incident on a solar cell, holes and electrons are generated. The holes diffuse into the p-type side of the P-N junction, and the electrons diffuse into the n-type side of the P-N junction to create a potential imbalance, thereby producing electric power. In order to increase the efficiency of the solar cell, an inner potential needs to be increased, or the amount of sunlight absorbed and converted into electricity needs to be increased. Because it is known that the highest efficiency of the solar cell varies according to materials used to form the solar cell, there is a limit to increasing the efficiency of the solar cell by changing only the materials.

Solar cells may be classified as substrate solar cells and thin film solar cells. Substrate solar cells use a semiconductor material (e.g., silicon) as a substrate. Thin film solar cells have a semiconductor layer formed as a thin film on a substrate, thereby enabling mass production.

### SUMMARY

Example embodiments relate to solar cell structures having a transparent conductor material formed on a surface of each of a p-type semiconductor layer and an n-type semiconductor layer.

Provided are solar cell structures wherein the mobility of holes or electrons generated in the solar cell structure is increased by fdrming a transparent semiconductor material on a surface of each of a p-type semiconductor layer and an n-type semiconductor layer.

According to example embodiments, a solar cell structure includes an n-type semiconductor layer, an i-type semiconductor layer, a p-type semiconductor layer and a transparent conductive layer including a transparent conductive material contacting each of the n-type semiconductor layer and the p-type semiconductor layer.

The transparent conductive layer may include a combination of metal and at least one selected from the group consisting of oxygen (O), nitrogen (N), sulphur (S), selenium (Se), tellurium (Te) and combinations thereof.

The transparent conductive layer may include indium tin oxide (ITO), zinc oxide (ZnO) or tin dioxide (SnO₂).

The n-type semiconductor layer, the i-type semiconductor layer, or the p-type semiconductor layer may include at least one selected from the group consisting of silicon (Si), copper indium gallium selenide (CIGS), cadmium telluride (CdTe) and combinations thereof.

According to example embodiments, a solar cell structure includes a first transparent conductive layer, an n-type semiconductor layer formed on the first transparent conductive layer, an i-type semiconductor layer formed on the n-type semiconductor layer, a p-type semiconductor layer formed on the i-type semiconductor layer and a second transparent conductive layer formed on the p-type semiconductor layer.

The second transparent conductive layer may include a material having a greater amount of oxidation than the first transparent conductive layer.

### BRIEF DESCRIPTION OF THE DRAWINGS

These and/or other aspects will become apparent and more readily appreciated from the following description of the embodiments, taken in conjunction with the accompanying drawings of which:

FIG. 1 is a cross-sectional view of a solar cell structure according to example embodiments;

FIG. 2 is an energy band diagram of the solar cell structure of FIG. 1; and

FIG. 3 is a graph showing current-voltage (I-V) measurement results for explaining the effect of a solar cell structure including a transparent conductive layer.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments relate to a solar cell structure having a transparent conductor material formed on a surface of each of a p-type semiconductor layer and an n-type semiconductor layer.

Example embodiments provide a solar cell structure configured as a PIN diode including an n-type semiconductor layer, an intrinsic (i)-type semiconductor layer and a p-type semiconductor layer, wherein a transparent conductive material is formed on each of the n-type semiconductor layer and the p-type semiconductor layer.

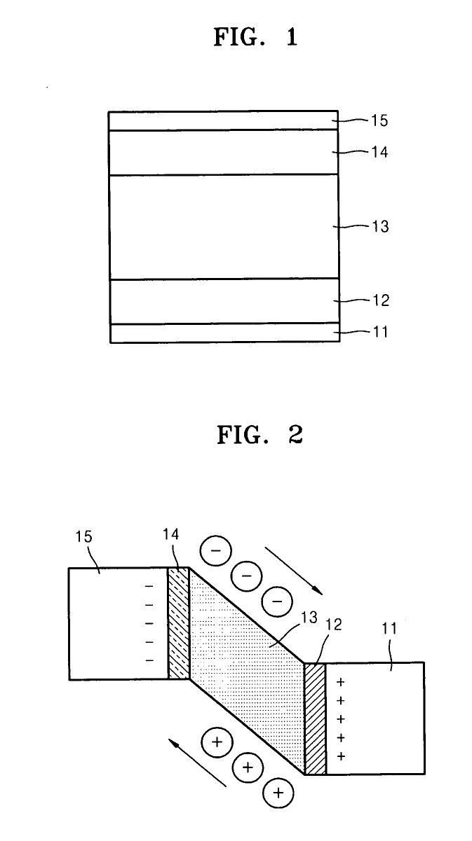

FIG. 1 is a cross-sectional view of a solar cell structure according to example embodiments.

Referring to FIG. 1, a first transparent conductive layer 11, an n-type semiconductor layer 12, an i-type semiconductor layer 13, a p-type semiconductor layer 14 and a second transparent conductive layer 15 are sequentially formed on a lower structure (not shown). The lower structure may be formed of glass, a semiconductor material or like materials.

Each of the first transparent conductive layer 11 and the second transparent conductive layer 15 is formed of a transparent conductive material that is a conductive metal oxide. For example, the transparent conductive material may be a combination of metal and oxygen. The transparent conductive material may be a combination of metal and nitrogen (N), sulphur (S), selenium (Se), or tellurium (Te). The transparent conductive material may be a combination of metal and at least one selected from the group consisting of O, N; S, Se, Te and combinations thereof. The transparent conductive material may include indium tin oxide (ITO), zinc oxide (ZnO) or tin dioxide (SnO₂). The first transparent conductive layer 11 and the second transparent conductive layer 15 may include a combination of metal and at least one non-metal selected from a Group 15 element, a Group 16 element and combinations thereof.

The second transparent conductive layer 15 contacting the p-type semiconductor layer 14 may be formed of a material having a greater amount of oxidation than the first transparent conductive layer 11 contacting the n-type semiconductor layer 12. For example, the first transparent conductive layer 11 may be formed of ZnO, and the second transparent conductive layer 15 may be formed of Zn₂O₃. The second transparent conductive layer 15 may include a material having a different amount of oxygen than the first transparent conductive layer 11. Because the second transparent conductive layer 15 is formed of a material having a greater amount of oxidation than the first transparent conductive layer 11, the mobility of holes and electrons, which are carriers, increases.

The n-type semiconductor layer 12 or the p-type semiconductor layer 14 may be formed by doping a semiconductor material (e.g., silicon (Si), copper indium gallium selenide (CIGS), cadmium telluride (CdTe) or combinations thereof) with an n-type or p-type dopant. The i-type semiconductor layer 13 may be formed of a semiconductor material.

The n-type semiconductor layer 12, the i-type semiconductor layer 13 and the p-type semiconductor layer 14 may be formed of a same semiconductor material. The n-type semiconductor layer 12, the i-type semiconductor layer 13 and the p-type semiconductor layer 14 may be formed of different semiconductor materials. The i-type semiconductor layer 13 may be formed of a different semiconductor material than the n-type semiconductor layer 12 and the p-type semiconductor layer 14.

The solar cell structure may be formed using sputtering, plasma chemical vapor deposition (CVD), metal organic chemical vapor deposition (MOCVD) or similar deposition methods.

FIG. 2 is an energy band diagram of the solar cell structure of FIG. 1.

FIG. 2 illustrates energy bands of the first transparent conductive layer 11, the n-type semiconductor layer 12, the i-type semiconductor layer 13, the p-type semiconductor layer 14 and the second transparent conductive layer 15. Because the solar cell structure is configured as a PIN diode including the n-type semiconductor layer 12, the i-type semiconductor layer 13 and the p-type semiconductor layer 14, holes and electrons, which are carriers, are generated due to an internal built-in potential and photon energy in sunlight.

The i-type semiconductor layer 13 is depleted due to the p-type semiconductor layer 14 and the n-type semiconductor layer 12, creating an electric field. The holes and the electrons respectively drift (or migrate) due to the electric field to the p-type semiconductor layer 14 and the n-type semiconductor layer 12.

At this time, a dipole is formed in the second transparent conductive layer 15 contacting the p-type semiconductor layer 14 and the first transparent conductive layer 11 contacting the n-type semiconductor layer 12 to generate an electrostatic force and accelerate the mobility of the holes and the electrons.

A region of the first transparent conductive layer 11 adjacent to the n-type semiconductor layer 12 is positively charged, and a region of the second transparent conductive layer 14 adjacent to the p-type semiconductor layer 13 is negatively charged. Accordingly, the solar cell structure may provide higher efficiency due to the first transparent conductive layer 11 and the second transparent conductive layer 15.

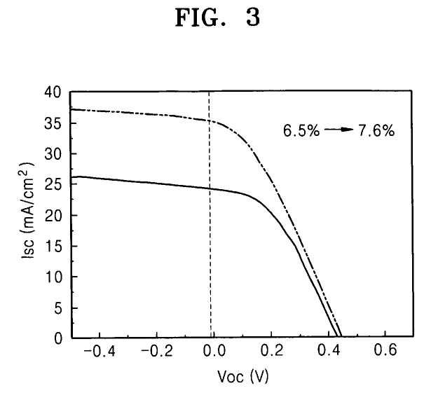

FIG. 3 is a graph showing current-voltage (I-V) measurement results for explaining the effect of a solar cell structure including a transparent conductive layer.

FIG. 3 shows the I-V measurement results of an experiment conducted on a solar cell structure sample including a first transparent conductive layer formed of ITO, an n-type semiconductor layer, an i-type semiconductor layer, and a p-type semiconductor layer each formed of silicon, and a second transparent conductive layer formed of ITO, and an experiment conducted on a solar cell structure sample having a PIN structure without including first and second transparent conductive layers. A solid line represents the measurement results for the solar cell structure sample without including the first and second transparent conductive layers, and a dotted line represents the measurement results for the solar cell structure sample including the first and second transparent conductive layers.

Referring to FIG. 3, the current of the solar cell structure sample including the first and second transparent conductive layers respectively formed on the n-type semiconductor layer and the p-type semiconductor layer is clearly larger compared to the solar cell structure without the first and second transparent conductive layers. Because the solar cell structure of FIG. 1 includes the first transparent conductive layer 11 and the second transparent conductive layer 15, the mobility of holes and electrons generated by sunlight is accelerated, thereby increasing the efficiency of the solar cell structure.

As described above, the efficiency of a solar cell structure configured as a PIN diode according to example embodiments increases by forming a transparent conductive material on each of a p-type semiconductor layer and an n-type semiconductor layer to increase the mobility of holes and electrons.

The solar cell structures according to example embodiments may be used in any devices that convert light into electricity using semiconductor technology. For example, the solar cell structures according to example embodiments may be used in commercial applications (e.g., spacecrafts, satellites and automotives), residential applications, and mobile applications (e.g., cell phones and outdoor lighting sources).

It should be understood that example embodiments described therein should be considered in a descriptive sense only and not for purposes of limitation. In detail, a transparent conductive material may be applied to a thin film-type solar cell structure using various semiconductor materials other than silicon, and is not limited to a metal oxide or a metal nitride. The thickness of each of the layers is not limited. Therefore, the scope of example embodiments is defined not by the detailed description but by the appended claims.

What is claimed is:

1. A solar cell structure, comprising:
an n-type semiconductor layer;
an i-type semiconductor layer on the n-type semiconductor layer; and
a p-type semiconductor layer on the i-type semiconductor layer;
wherein the n-type semiconductor layer and the p-type semiconductor layer each respectively contacts a transparent conductive layer having a transparent conductive material.

2. The solar cell structure of claim 1, wherein the transparent conductive layer includes a combination of metal and at least one selected from the group consisting of oxygen (O), nitrogen (N), sulphur (S), selenium (Se), tellurium (Te) and combinations thereof.

3. The solar cell structure of claim 1, wherein the transparent conductive layer is a conductive metal oxide.

4. The solar cell structure of claim 1, wherein the transparent conductive layer includes a combination of metal and at least one non-metal selected from a Group 15 element, a Group 16 element and combinations thereof.

5. The solar cell structure of claim 1, wherein the transparent conductive layer include at least one selected from the group consisting of indium tin oxide (ITO), zinc oxide (ZnO), tin dioxide (SnO₂) and combinations thereof.

6. The solar cell structure of claim 1, wherein the n-type semiconductor layer, the i-type semiconductor layer and the p-type semiconductor layer include at least one semiconductor material selected from the group consisting of silicon (Si), copper indium gallium selenide (CIGS), cadmium telluride (CdTe) and combinations thereof.

7. The solar cell structure of claim 1, wherein the n-type semiconductor layer, the i-type semiconductor layer and the p-type semiconductor layer are formed of a same semiconductor material.

8. The solar cell structure of claim 1, wherein n-type semiconductor layer, the i-type semiconductor layer and the p-type semiconductor layer are formed of different semiconductor materials.

9. The solar cell structure of claim 1, wherein the i-type semiconductor layer directly contacts the n-type semiconductor layer,
the p-type semiconductor layer directly contacts the i-type semiconductor layer, and
the n-type semiconductor layer and the p-type semiconductor layer directly contact the respective transparent conductive layer.

10. The solar cell structure of claim 1, wherein the transparent conductive layer contacting the n-type semiconductor layer is a first transparent conductive layer, the n-type semiconductor layer being on the first transparent conductive layer, and
the transparent conductive layer contacting the p-type semiconductor layer is a second transparent conductive layer on the p-type semiconductor layer.

11. The solar cell structure of claim 10, wherein the second transparent conductive layer includes a material having a greater amount of oxidation than the first transparent conductive layer.

12. The solar cell structure of claim 11, wherein the second transparent conductive layer is formed of ZnO and the first transparent conductive layer is formed of Zn₂O₃.

13. The solar cell structure of claim 10, wherein the second transparent conductive layer includes a material having a different amount of oxygen than the first transparent conductive layer.

14. The solar cell structure of claim 10, wherein the first transparent conductive layer and the second transparent conductive layer includes a combination of metal and at least one selected from the group consisting of O, N, S, Se, Te and combinations thereof.

15. The solar cell structure of claim 10, wherein the first transparent conductive layer and the second transparent conductive layer includes ITO, ZnO, SnO₂ or combinations thereof.

16. The solar cell structure of claim 10, wherein the n-type semiconductor layer, the i-type semiconductor layer and the p-type semiconductor layer includes at least one selected from the group consisting of Si, CIGS, CdTe and combinations thereof.
